(19) United States
(12) Patent Application Publication
(10) Pub. No.: US 2002/0190759 A1
(43) Pub. Date: Dec. 19, 2002

(54) Electrochemically accelerated self-assembly of molecular devices

(76) Inventors: James M. Tour, Houston, TX (US); Jiping Yang, Houston, TX (US); Philipp Harder, (US); David L. Allara, (US); Paul Weiss, State College, PA (US)

Correspondence Address: CONLEY ROSE & TAYON, P.C., P. O. BOX 3267, HOUSTON, TX, 77253-3267, US

(21) Appl. No.: 10/090,211

(22) Filed: Mar. 4, 2002

Related U.S. Application Data
(60) Provisional application No. 60/272,895, filed on Mar. 2, 2001.

(51) Int. Cl. G01R 1/00; H03D 1/00; H03K 5/00; H03K 9/00

(52) U.S. Cl. 327/1

(57) ABSTRACT

A method for selectively assembling a molecular device on a substrate comprises contacting the first substrate with a solution containing molecular devices; impeding bonding of the molecular devices to the substrate such that application of a voltage potential to the substrate results in assembly of the molecular device on the substrate at a rate that is at least 1.5 times the rate of assembly of the molecular device on a voltage-neutral substrate; and applying a voltage potential to the substrate so as to cause the molecular devices to assemble on the substrate. More specifically, selective assembly can be obtained by providing a mixture comprising protected molecular devices in solution; removing protective groups from some of the molecular devices; activating the de-protected molecular devices; contacting the substrate with the solution; and allowing the activated devices to bond to the substrate such that the they assemble on the first substrate.

### CROSS-REFERENCE TO RELATED APPLICATIONS

This application claims benefit of priority from U.S. application Ser. No. 60/272,895, filed Mar. 2, 2001, and entitled “Electromechanically Accelerated Self-Assembly Of Molecular Devices,” which is incorporated herein by reference in its entirety.

### STATEMENT REGARDING FEDERALLY SPONSORED RESEARCH OR DEVELOPMENT

This work was supported by the Defense Advanced Research Projects Agency (DARPA), the Office of Naval Research (ONR), and the National Science Foundation (NSF, NSR-DMR-0073046).

### TECHNICAL FIELD OF THE INVENTION

The present invention relates generally to a method for assembling molecular devices. More particularly, the present invention relates to the use of voltage to enhance the selective assembly of a desired composition on a desired metal surface.

### BACKGROUND OF THE INVENTION

Molecular scale electronics is an emerging field that proposes the use of single molecules or small groups of molecules to function as the key components in computational devices. The concept is based on the use of molecules or groups of molecules that transmit current either linearly or non-linearly when subjected to a voltage potential. In particular, molecules or groups of molecules that have linear I/V curves can resemble wires and are termed “molecular wires,” or sometimes “molewires.” Molecules or groups of molecules that have non-linear I/V curves can resemble other types of electronic devices and are therefore termed “molecular components,” “molecular switches,” or sometimes “moleswitches.” The term “molecular device” will be used herein to denote all such molecular-scale conducting devices.

It is becoming more widely accepted that, given a sufficient selection of operable molecular devices, molecular-scale computers could be constructed using principles similar to those used to construct conventional, semiconductor-based computers. In addition to the substantial size reductions that would result, the response times of molecular devices can be in the range of femto-seconds, while the fastest present devices operate in the nanosecond regime. Thus, a significant increase in speed may be attainable, particularly if other circuit elements do not limit operational performance. Different substitution groups can be used to provide molecular devices with a variety of electronic properties, such as negative differential resistance (NDR), molecular memory capability, and molecule-scale switching behavior.

An ongoing challenge in implementing molecular scale electronics has been the search for techniques that will allow the controlled assembly of molecular devices. While self-assembled monolayers (SAMs) of conjugated thiols on Au have drawn considerable attention due to their potential use in molecular electronics and have been shown to serve as molecular device components, controlled, precise placement of such SAMs in a manner that would allow them to function as molecular devices has not heretofore been possible. The success of molecular computing depends in part on the precise placement of molecular device components on a patterned substrate. Thus, in some instances, it becomes crucially important to accurately direct the assembly of the components onto specific electrodes. Conventional chemical self-assembly techniques cannot furnish such selectivity.

Several groups have reported successful electrochemical oxidative adsorption of alkane thiols on various surfaces, such as Au, Ag, and Hg. Recently, Hsueh and co-workers reported the electrochemical oxidation of alkylthiosulfate (R—S₂O₃—) on Au electrodes at +1200 mV (versus Ag/AgNO₃). Monolayer formation took place preferentially on the biased Au electrodes, while the electrodes that were not biased experienced slower adsorption. However, the thiosulfate method produces alkylsulfide radicals and has been demonstrated so far only with simple n-alkane derivatives.

Potential-enhanced self-assembly of certain alkanethiols that are not molecular devices is also known, but, until now, no one has yet discovered how to effect controlled, selective assembly of molecular devices on designated substrates under mild electric potentials. It has been observed that thiol-based molecules assemble almost equally rapidly on non-charged surfaces as on charged surfaces. The similar behavior of charged and non-charged surfaces has heretofore made it impossible to use voltage-assisted assembly to apply molecular device layers in a controlled or targeted manner.

Hence, there is still a need for methods that allow small, i.e. molecular scale, devices to be assembled quickly and accurately and in a controlled or targeted manner. A preferred method would allow the application of desired layers without undue expense.

### BRIEF SUMMARY OF THE INVENTION

The present invention solves the problems associated with the prior art inasmuch as it allows controlled, selective assembly of molecular devices on metal electrodes under mild electric potentials and thus provides a method for assembling molecular scale devices quickly and accurately and without undue expense.

The present invention comprises using a small voltage potential to drive the free thiols or thiolates to assemble on a metal surface. By impeding the rate of formation of thiolates in combination with the use of a voltage potential, sufficient differentiation between adjacent surfaces can be achieved to allow selective assembly of molecular devices.

### BRIEF DESCRIPTION OF THE DRAWINGS

For a detailed understanding of the present invention, reference is made to the accompanying Figures, wherein:

FIG. 1 illustrates six exemplary molecules that can be selectively assembled according to the present invention;

FIG. 2 is a schematic overview of the steps involved in a preferred embodiment of the present method;

FIG. 3 is a plot of the growth rate of a layer of molecule (a) on an Au surface in the absence of potential;

FIG. 4 is plot showing cyclic voltammograms of a gold electrode in a solution of KCl/K₃[Fe(CN)₆](0.1 M/1 mM);

FIG. 5 is a plot showing cyclic voltammograms of a gold electrode covered with molecular device (a) of FIG. 1;

FIG. 6 is a plot showing cyclic voltammograms of a platinum electrode covered with molecular device (a) of FIG. 1;

FIG. 7 is a comparison between a layer of molecular device (a) in a KBr matrix (top) and monolayers on a gold electrode that were grown electrochemically or adsorbed from solution without potential;

FIG. 8 illustrates six exemplary molecules that can be selectively assembled according to an alternate embodiment of the present invention; and

FIGS. 9-14 are illustrations of various molecules that can be used in the methods of the present invention to form molecular devices.

### DETAILED DESCRIPTION OF THE INVENTION

It has been discovered that molecular devices can be selectively assembled on desired substrates quickly and with a high degree of precision. According to a preferred embodiment of the present invention, the difference in the rates of assembly of a given molecular device on a given metal substrate can be used to control the placement of the molecular device. More particularly, applicants have discovered a technique for slowing the assembly of molecular devices on a non-charged surface. As a result, the use of a small voltage sufficiently accelerates the rate of assembly that the present methods can be used to selectively assemble molecular devices on substrates that are at least as close together as 0.3 μm.

According to one aspect of the present invention, thiol-terminated molecular devices are de-protonated in a basic solution, thereby forming thiolates. Thiolates assemble on charged and non-charged surfaces, but the rate of assembly on selected surfaces is greatly enhanced by the application of a voltage potential to those surfaces. According to another embodiment, free thiols are formed from protected molecular device molecules in an acidic solution. If the rate of formation of the fee thiol is slowed sufficiently, a layer can be selectively formed by enhancing the rate of deposition on a selected surface. While the bulk of the discussion below is presented in terms of the basic technique, the concepts set out herein are intended to include not only acidic and basic schemes, but any other scheme by which the rate of assembly of molecular device molecules can be impeded and selectively enhanced so as to allow for selective application.

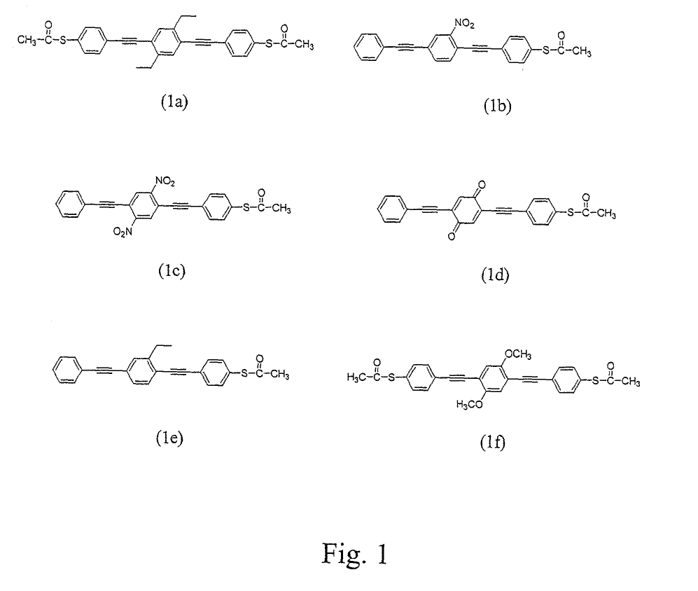

Referring initially to FIG. 1, several thioacetates that are suitable for use in the present invention are shown. While the molecules illustrated in FIG. 1 are known to be effective in the present process, the present invention is not limited to the molecules shown in FIG. 1. Additional suitable molecular device molecules, along with schemes for making them, can be found in Tour, J. M.; Rawlett, A. M.; Kozaki, M.; Yao, Y.; Jagessar, R. C.; Dirk, S. M.; Price, D. W.; Reed, M. A.; Zhou, C.; Chen J.; Wand, W.; and Campbell, I. Chem. Eur. J. 2001, 7, No. 23, 5118-5134, which is incorporated herein by reference in its entirety. In addition, any of the molecular devices taught in Chen, J.; Reed, M. A.; Rawlett, A. M.; Tour, J. M. Science 1999, 286, 1550, Chen, J.; Wang, W.; Reed, M. A.; Rawlett, A. M.; Price, D. W.; Tour, J. M. Appl. Phys. Lett. 2000, 77, 1224, or Bumm, L. A.; Arnold, J. J.; Cygan, M. T.; Dunbar, T. D.; Burgin, T. P.; Jones, L., II; Allara, D. L.; Tour, J. M.; Weiss, P. S. Science 1996, 271, 1705, all of which are incorporated herein by reference, can be used in the present invention.

Specifically, molecular devices that are suitable for use with the present invention include pi-conjugated aromatics and in particular, and in particular protected thiol-terminated oligo(phenylene ethynylene)s, are preferred for use as molecular devices.

According to the present invention, the thiol-terminated molecular devices need to include on each thiol a protective group that can be removed by the application of a desired chemical or electrochemical stimulus. It has been discovered that the presence of the protective group sufficiently slows the rate of formation of thiolate in a basic solution, or thiol in an acidic solution, that the voltage applied to an electrode surface will cause the molecules to assemble on that surface significantly faster than on a non-charged surface in the same solution. Furthermore, a pH neutral solution could be used in a similar scheme, wherein the thiol protecting group is removed electrochemically.

In one preferred embodiment, the stimulus is a voltage potential and the protective group is selected from the protective groups identified in Greene, T.; Wuts, P. Protective Groups in Organic Synthesis, 3d ed. (1999), which is incorporated herein by reference. Particularly preferred are the protective groups listed in chapter six of that reference, including thioethers, S-diphenylmethyl thioethers, substituted S-diphenylmethyl thioethers, and S-triphenylmethyl thioethers, substituted S-methyl derivatives, substituted S-ethyl derivatives, silyl thioethers, thioesters, thiocarbonate derivatives, and thiocarbamate derivatives. Also particularly preferred are thioacetates, sometimes called thioacetyl groups or thiolacetates, also known by the formula SCOCH₃. A thiol-terminated molecular device protected in this manner will be referred to herein as a “monolayer precursor.” The exemplary molecules shown in FIG. 1 are S-acetyl-oligo(phenylene ethynylene)s.

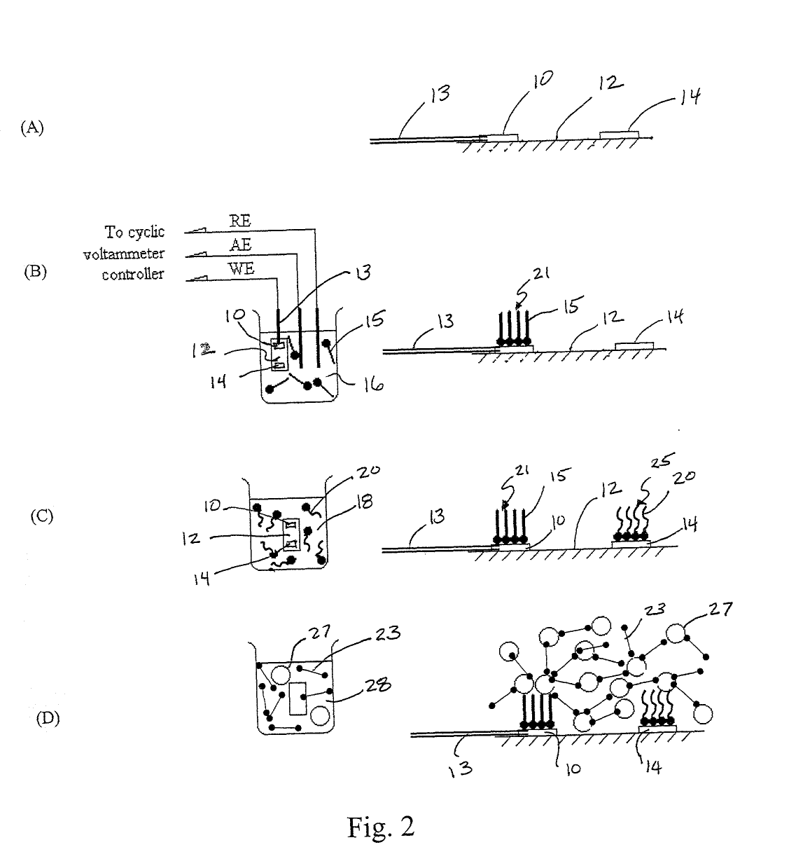

Referring now to FIG. 2, the present method can be used to selectively assemble a first monolayer on at least one substrate 10, which may be affixed to a base 12 adjacent to a second substrate 14. One preferred embodiment of the present method includes electrically connecting a conducting lead 13 to the first substrate 10, as shown in FIG. 2(A). With lead 13 in place, base 12, carrying substrates 10 and 14, can be placed in a solution 16 containing the desired monolayer precursor molecules 15, as shown in FIG. 2(B).

A voltage potential is applied to the first substrate 10 via lead 12. In FIG. 2(B), lead 13 is identified as the working electrode (WE), and is used in a conventional manner in conjunction with a reference electrode (RE) and an auxiliary electrode (AE). It is not necessary to wait until the substrate 10 is submerged in the solution 16 to apply the voltage. Application of the voltage causes a layer of the desired precursor molecules 15 to assemble into a monolayer 21 on the surface of substrate 10.

According to the present invention and as described above, the monolayer precursor molecules 15 each include a protective group that prevents or impedes rapid assembly of the monolayer on the substrate in the absence of a potential to draw the low concentration of free thiol or thiolate to the surface. Depending on the precursor used, solution 16 can be either an acidic or basic solution. Without being bound by the following, it is speculated that the presence of a base causes the protective groups on certain monolayer precursor molecules to disassociate from the precursor molecules. The de-protected thiol groups on the precursor molecules are then deprotonated by the base, forming charged thiolate groups. These charged thiolate groups, in turn, are attracted to the positively charged electrode (substrate 10) and assemble there. Similarly, we have discovered the methods of the present invention can be used advantageously in acidic solutions, albeit via a different mechanism. In acidic solutions, the terminal groups on the molecular device precursors do not form thiolates, and instead form free thiols, which, like thiolates, are advantageously drawn to the charged surface.

It has been discovered that even though some monolayer precursors molecules may assemble on second substrate 14 while the layer is assembling on first substrate 10, the disparity between the rates of assembly on the charged and non-charged substrates is great enough to allow selective assembly. More particularly, the use of a protective groups on the precursor prevents the thiol groups from assembling and impedes formation of thiolate groups, while the application of a voltage potential to first substrate 10 accelerates the rate of assembly on substrate 10. The combination of these effects separates the rates of assembly on the two substrates to such a degree that the amount of monolayer that assembles on second substrate 14 during the time required to assemble a desired layer on first substrate 10 is relatively insignificant. For example, in some systems, the acetate-impeded, potential-assisted assembly is one to two orders of magnitude faster than acetate-impeded, non-potential-assisted assembly. The overall rate of assembly is partially dependent on molecular structure. According to the present invention, similar differentiation can be also achieved when the protective group is other than an acetate group.

Referring still to FIG. 2, following the selective placement of a monolayer on one or more of the substrates 10, the base 12 can be placed in a second solution 18 containing second precursor molecules 20. The second precursor is preferably but not necessarily a molecular device. Also, the second precursor may be protected or not protected, and the assembly of the second precursor into a monolayer can be voltage-assisted or not. Because the surface of the first substrate is already covered with the first monolayer 15, molecules of the second precursor do not rapidly bond to substrate 10. It is an advantage of the present invention that the de-protected, deprotonated thiolate of the present invention generally shows relatively slow tendency to displace an already-formed monolayer. Once a second monolayer 25 has formed on substrate 14, base 12 can be removed from solution 18 and placed in a third solution 28, which may contain precursors 23 for additional molecular devices and/or metal nanoparticles 27, such as are known in the art. Hence, it is possible to apply different molecular device species sequentially without affecting previously applied layers. By applying different molecular devices sequentially using the present methods, it becomes possible to construct a complex device. In a particularly preferred embodiment, precursors 23 comprise conjugated molecules that have a thiol on each end, such as could be generated from FIG. 1(a).

It has further been discovered that the application of a voltage potential to one substrate affects only those precursor molecules that are very close to that substrate. Thus, the present method has been used to selectively produce a monolayer on one of two substrates that are separated by gaps as small as 0.3 μm and it is expected that substrate differentiation could be achieved across even smaller distances, with the lower limited being defined only by the limits of lithography or other types of patterning, such as electron beam. Hence, the present method is suitable for use in the construction of micro- or nano-electronic devices.

Another advantage of the present invention is that it allows the rapid assembly rate associated with thiolate or thiol assembly without requiring storage or handling of thiolate or thiol solutions. Specifically, thiolates and aromatic thiols are unstable against oxidation, while thioacetates can be stored for extended periods in air without degradation. According to the present invention, the convenience of having a thioacetate stock solution can be combined with a rapid adsorption.

It has further been discovered that molecular device components containing electron-donating groups assemble faster than those with electron-withdrawing groups. For example, using the present invention, one can deposit molecules with electron donating groups, e.g. FIG. 1 (f), on one electrode, followed by the deposition of molecules with electron withdrawing groups, e.g. FIG. 1(c), on another electrode. The formation of different layers on adjacent substrates is illustrated schematically in FIG. 2. By bridging the two molecular wire-decorated electrodes with a conducting material, one may observe device behavior.

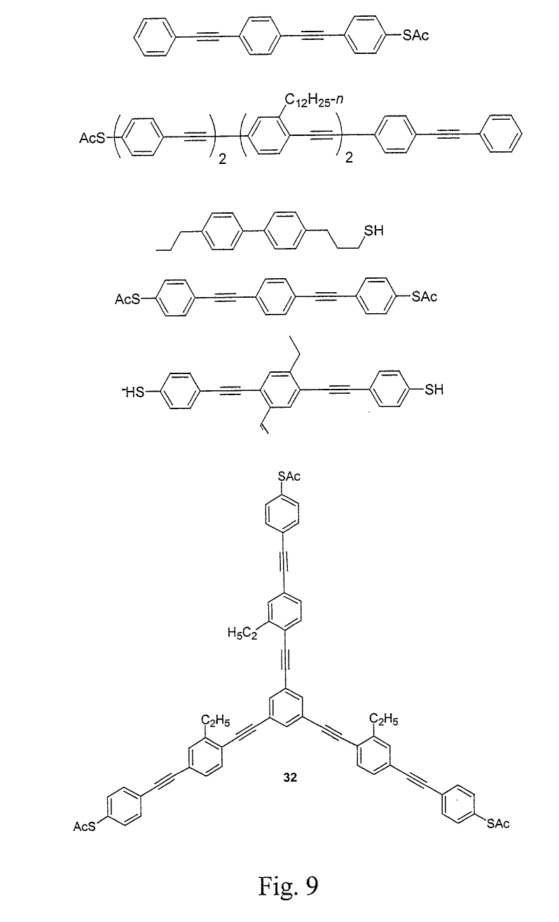

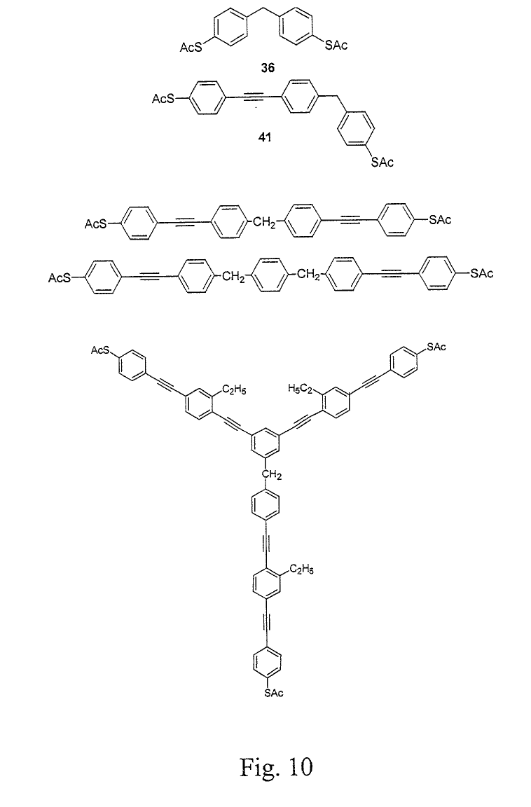

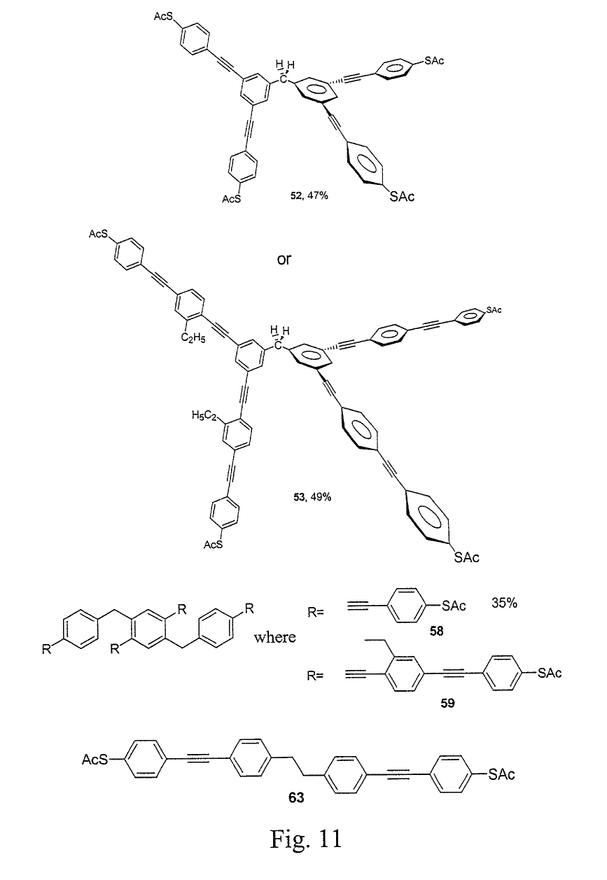

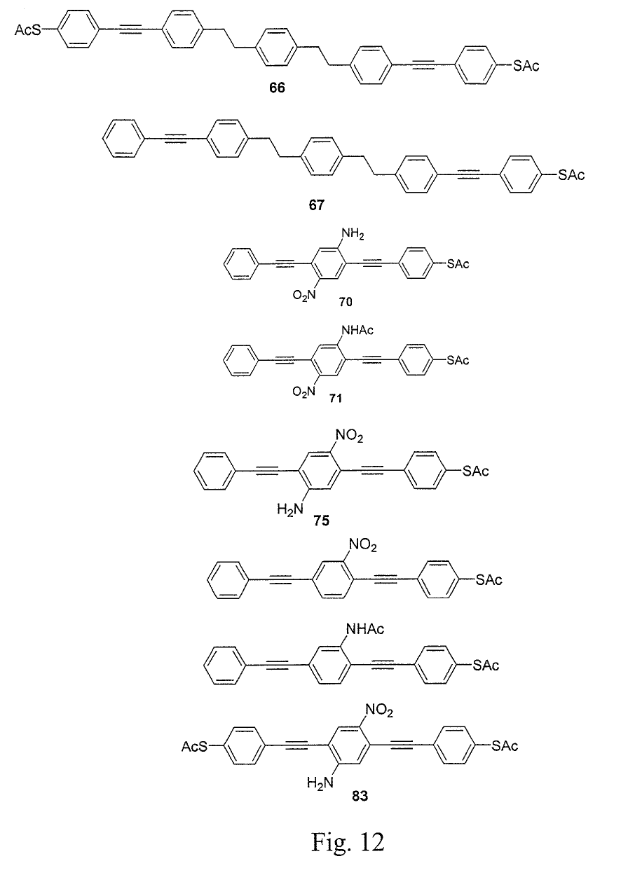

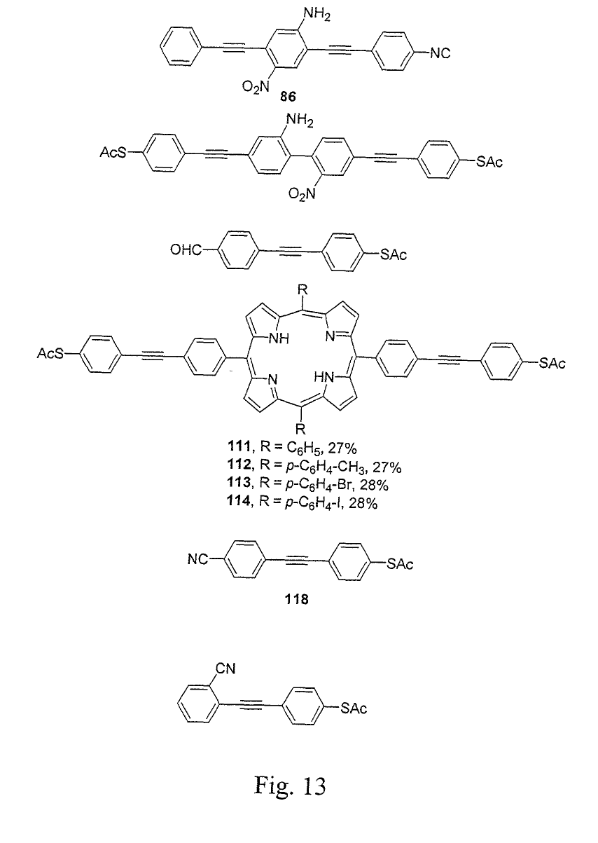

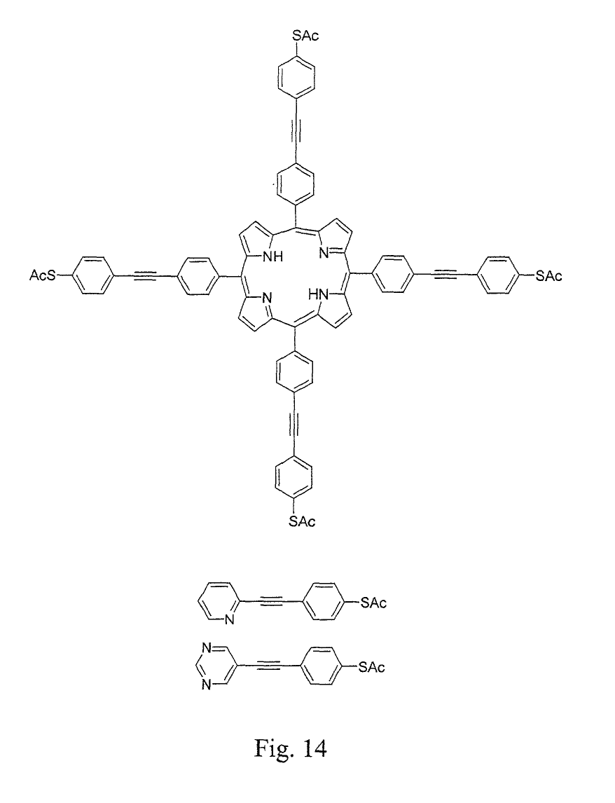

One skilled in the art of molecular devices will recognize that the principles of the present invention are applicable to systems that include a variety of molecular device molecules. The molecular devices that can be applied or selectively applied using the present techniques include but are not limited to the various molecules shown in FIGS. 9-14.

The concepts of the present invention are useful with metal substrates generally, and more particularly with the coinage metals or late transition metals, including but not limited to gold, palladium, silver, copper and platinum.

Similarly, the metal-bonding terminus of the present invention can be other than sulfur. For example, selenium and tellurium can be substituted for the sulphur. Hence, the present invention is not limited to thiol-terminated molecular devices, but also includes selenol and tellurolsm, as is known in the art. See, for example, Reinerth, W. A.; Tour, J. M. “Protecting Groups for Organoselenium Compounds,” J. Org. Chem. 1998, 63, 2397-2400.

Solvents that are useful in the present invention include but are not limited to alcohols, water, and any nonreactive organic solvent, or combination thereof. Similarly, the electrolyte can be any soluble ionic salt that is not corrosive to the electrode.

The identity and orientation of the molecular device components on the metal surface is another important issue for the present electrochemical assembly technique. The average orientation of compound (a) on the surface can be derived from the relative intensities of a pair of IR absorption bands that correspond to molecular vibrations that are either parallel or perpendicular to the oligo(phenylene ethynylene) axis. A random orientation would give the same relative band intensities in both the external reflection IR spectrum of the monolayer and the transmission spectrum of the bulk sample. In contrast, an ordered orientation of the molecules will show an increased intensity of the parallel vibrations. If the molecules tilt towards the surface (angle >54.7°) the perpendicular bands will dominate the monolayer spectrum. IR spectra of substrates selectively coated according to the present invention confirm that monolayers are present. Layers deposited according the present technique have structures that are similar to the structures of layers deposited in a conventional, non-potential assisted manner.

Conclusions

The rate of assembly of thiolate-terminated oligo(phenylene ethylene) molecular device components under electric potential is greatly enhanced. A low thiolate concentration can be maintained by the in situ deprotection of some part of a thioacetate derivative stock solution. The accelerated adsorption on positively charged electrodes, combined with a low thiolate concentration in solution, makes it possible to selectively deposit molecules onto specific electrodes. The molecular orientation in the SAM made under electric potential is similar to the SAM made by conventional self-assembly technique. The in-situ cleavage of the thioacetate derivative reduces the problems with the instability of the thiolate or thiol solution. The thioacetate itself adsorbs only slowly on metal surfaces. Similar rate differentiation and selectivity can be obtained using a basic solution. The acid solution techniques is preferred for some molecular devices as it results in a more intact layer.

### EXAMPLES

The following Example are intended to illustrate the efficacy of certain embodiments of the invention and are not intended to be limiting in any way.

Self-Assembly of Thiolates on Gold Using Base Deprotection.

Materials.

Ethanol (Pharmco Products Inc., 200 proof, USP Grade) was degassed with nitrogen prior to use. THF (Aldrich) was freshly distilled from Na/benzophenone under an atmosphere of nitrogen, and used immediately. Tetrabutylammonium tetrafluoroborate was purchased from Aldrich and used without further purification. The syntheses of the oligo(phenylene ethynylene)s are known, and are described in the references identified above. Au substrates were prepared by the sequential deposition of Cr (50 nm) and Au (120 nm) onto a clean single crystal Si wafer. Metal depositions were carried out using an Auto 306 Vacuum Coater (Edwards High Vacuum International) at an evaporation rate of ˜1 Å/s and a pressure of ˜4×10⁻⁶ mm Hg. Pt substrates were prepared by sputtering a ˜50 nm layer of chromium (CrC-100 sputtering systems from Plasma Sciences, Inc.), followed by a 120 nm layer of Pt on clean surfaces of single crystal Si wafer. Au substrates were cleaned immediately prior to use by placing them in an aqueous solution of H₂O₂/NH₄OH (H₂O₂:NH₄OH:H₂O=1:1:5) for 15 min, followed by a thorough washing with deionized water and ethanol. Pt substrates were used without further cleaning.

Self-assembly of thioacetates on Au was carried out in a vial which contained a piece of the Au substrate, the oligo(phenylene ethynylene) compound (1.0 mg), ethanol (20 mL), and NaOH (20 μL of a 0.27 M solution, final concentration 0.27 mM). The sample was removed and washed with acetone, THF and ethanol.

Electrochemical Assembly.

Solutions for the potential-driven electrochemical assembly were prepared as follows: To a vial was added ethanol (20 mL), an oligo(phenylene ethynylene) (1.0 mg), tetrabutylammonium tetrafluoroborate (0.33 g, 1 mmol), and 20 μL of aqueous 0.27 M NaOH. A CV-50W Voltammetric Analyzer (BAS, Bioanalytical Systems, Inc) was used to control the electrical potential applied to the electrodes. The auxiliary electrode was Pt wire and a nonaqueous Ag/AgNO₃ electrode was used as the reference. One of the following working electrodes was used: evaporated Au or Pt, an Au disk electrode, or a Pt disk electrode. The potential applied to the working electrode was +400 mV (vs Ag/AgNO₃ electrode). Assembled samples were washed with acetone, deionized water, and briefly sonicated in ethanol.

Measurements.

The thicknesses of the self-assembled monolayers were measured using an ellipsometer (Rudolph Instruments, Model: 431A31WL633). The He-Ne laser (632.8 nm) was incident at 70° to the sample surface. A refractive index (nf) of 1.55 was used for the film thickness calculation. Cyclic voltammograms were recorded by a CV-50W Voltammetric Analyzer (Bioanalytical Systems, Inc), employing a Pt counter electrode and a saturated calomel reference electrode (SCE). The working electrode was an Au electrode (MF-2014, Bioanalytical Systems, Inc.) or a Pt electrode (MF-2013, Bioanalytical Systems, Inc.) covered with a given oligo(phenylene ethynylene). The diameter of the Au and Pt electrodes was 1.6 mm. Cyclic voltammetry was performed in an aqueous solution of KCl/K₃[Fe(CN)₆] (0.1 M/1.0 mM) using a potential scan rate of 100 mV/s.

Infrared Spectroscopy.

The orientation and thickness of assembled monolayer were checked using IR analyses. Details about the procedure and instrumentation used for the external reflection and transmission IR measurements are known in the art.

Discussion

There are three possible electrochemical methods for the deposition of molecular devices onto selected electrodes: 1) One can selectively deposit thiols on a biased Au electrode in the presence of an unbiased electrode. This method, to be useful, requires an appreciable different assembly rate between the biased and unbiased electrodes. 2) Conversely, one can permit assembly on an unbiased electrode while using a high potential to prevent assembly on the other electrode. 3) Lastly, one can uniformly form a SAM on both electrodes, then restore one electrode to its original bare state by the selective application of a high potential. For molecular electronic applications, the first approach is preferred. As described above, the present invention provided a technique for accomplishing the first method by allowing the molecules to assemble at a faster rate on the electrodes that are subjected to the potential than on the electrodes without potential.

Thiol Adsorption Kinetics on Au with and without Base or Electrostatic Potential

TABLE 1
Thiol adsorption under open circuit conditions and with applied potential.

| | Film thickness [nm] | | | | |
|---|---|---|---|---|---|
| | Adsorption | | | | |
| Thiol Species | conditions^{a} | 1 min | 10 min | 30 min | 24 h |

| | | | | | |
|---|---|---|---|---|---|
| 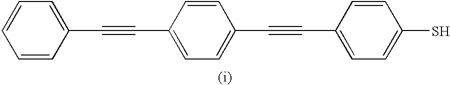 | Open circuit Open circuit +base +400 mV +400 mV +base | 1.7 1.8 2.0 6.5 | 1.8 1.8 2.7 | 2.0 | 2.4 |
| 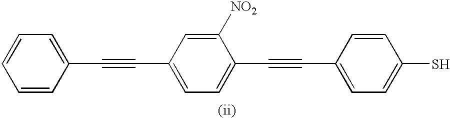 | Open circuit Open circuit +base +400 mV +400 mV +base | 1.5 2.1 | 1.7 2.5 | | 2.4 |
| 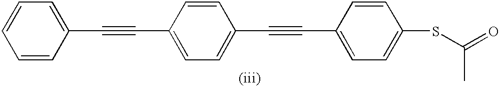 | Open circuit +400 mV | 0.3 0.2 | | 0.5 0.2 | |

^{a}The relative potentials were determined against a AgCl coated Ag wire in contact with the adsorption solution.

Alkanethiol adsorption isotherms typically show an initial rapid rise until the coverage reached 80-85% of a monolayer, followed by a second, slower step. Greater than 40% coverage was usually reached within the first 500 msec if the thiolate concentration was 1 mmol and within less than 60 sec. for a 1 μmol concentration. Overall, the aromatic thiol adsorption was found to be slower than the n-alkanethiol adsorption.

Approximately 0.1 mM solutions of the preferred thiol-terminated oligo(phenylene ethynylene)s in ethanol reach a half monolayer coverage in less than 1 minute. Their low solubility in ethanol probably compensates for the slower diffusion rate (Table 1). The addition of 1 μL 0.27 M NaOH per mL solution was found to have no significant influence on the adsorption rate.

A positive potential accelerates the thiol adsorption in the absence of a base and much more in combination with a base. The less soluble unsubstituted thiol shown at (i) in Table 1 forms a multilayer rapidly, and the more soluble nitro-substituted thiol (ii) reaches its theoretical monolayer thickness in 1 min instead of ˜1 h.

Thioacetates adsorb much more slowly than thiols. A solution with 1 mg of thioacetate 1(b) per 20 mL ethanol, or roughly 0.1 mM concentration, gives an 0.2 nm thick layer within 30 min, but the same was observed with a solution without thioacetate. Therefore, any layer formation can be attributed to advantageous adsorbate impurities, rather than to the thioacetate itself.

Assembly of Thioacetates with Base but without Potential

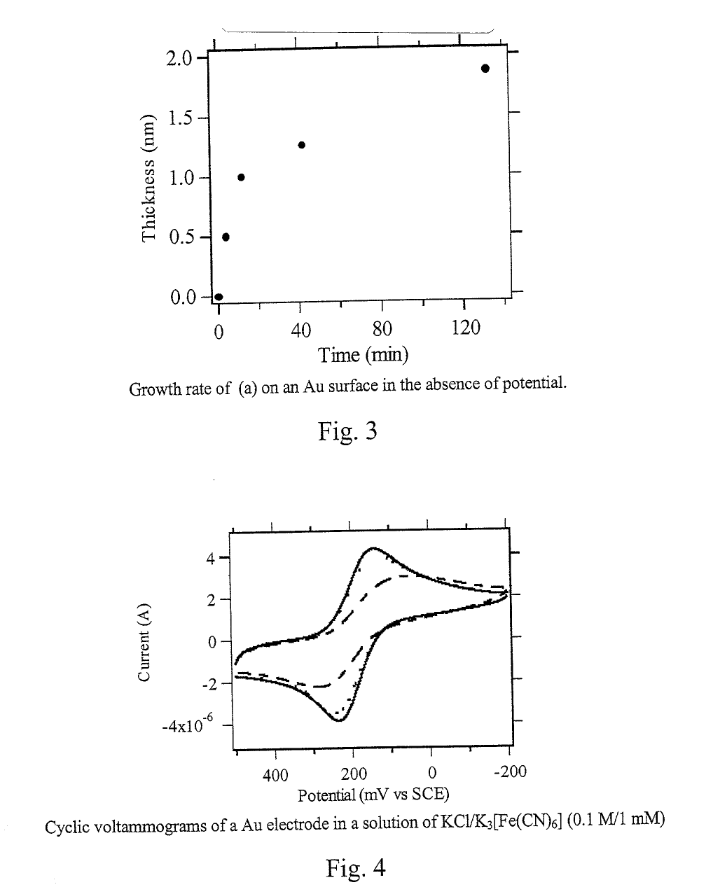

A 0.1 mM ethanolic solution of compound (a), which is shown in FIG. 1 and features two protected thiol termini, was assembled on Au after adding 1 μL 0.27 M NaOH per mL solution and the change in thickness over time was measured (FIG. 3). The adsorption was slower than for the free thiol despite the thioacetate groups on both ends.

Cyclic voltammetry (CV), as an indication of the surface coverage ratio, corroborated the ellipsometry measurements. FIG. 4 shows the cyclic voltammogram of an Au electrode before and after immersion in a solution of (a). In FIG. 4, the solid line indicates the bare Au electrode; the dotted line corresponds to the Au electrode after immersion in 20 mL of 0.1 mM ethanolic solution of (a) with 20 μL aqueous solution of 0.27 M NaOH for 2 min.; and the dashed line corresponds to the Au electrode after immersion in the same solution for 10 min. After immersion for 2 min., the peak current intensity dropped ˜10 % and after immersion for 10 min., the peak current intensity dropped ˜55%, indicating that the surface coverage ratio of (a) on the Au electrode was ˜10% after 2 min and ˜55% after 10 min; in good agreement with the ellipsometry data.

Compounds containing electron-withdrawing groups and only one thioacetate end assembled even more slowly. Compound (b), for example, with a nitro group on the central phenyl ring, took 15 min to reach a film thickness of 0.4 nm.

The least polar methylmercapto-terminated biphenylthiols adsorbed 7 times faster than electron rich N,N-dimethylamino-terminated thiols and 20 times faster than electron poor nitro-terminated ones. Electron donor groups increase the gold sulfur binding energy but destabilize the monolayer because of their repulsive intermolecular dipole-dipole interactions. The slow adsorption of aromatic thiols with electron acceptor end groups is due to a weaker sulfur binding energy and stronger intermolecular electrostatic repulsion.

The majority of the deprotected thioacetate molecules in ethanol dissociate to thiolates with a high electron density on the sulfur, no matter what the substitutents are. The initial adsorption rates for a 0.1 mmol aromatic thioacetate/thiolate mixture without applied potential are however 1-2 orders of magnitude lower than for aromatic thiols: 2 min for 10% surface coverage versus less than 5 sec with aromatic thiols. The reaction between neutral ArS—H as a soft base and Au as a soft acid is fast, according to the hard-soft acid-base (HSAB) principle, while the thiolate adsorption on gold requires another molecule to become simultaneously reduced.

The relatively faster adsorption of dithiolates and thiolates with electron donor groups correlates again with a higher gold sulfur binding energy but also with their lower dissociation constant. Electron acceptor groups shift the equilibrium to the dissociated and slowly-adsorbing thiolate, while donor groups reduce the acidity of the thiol proton.

The positive potential on the gold adds an attractive force between the surface and the negatively charged thiolates without changing the thiol dissociation equilibrium. The attraction is strongest for the electron-rich thiolates where the negative charge is located at the sulfur atom. A positive potential therefore further increases the adsorption rate for the already preferred thiolates with electron donor groups. The foregoing observations are included for the purpose of illustration only and are not intended to define the chemical mechanisms involved in the present invention or to limit the scope of the claimed invention.

Assembly of Molecular Devices with an Applied Voltage

Table 2 summarizes the results of electrochemical assembly of a series of thioacetate derivatives on Au when a small amount of sodium hydroxide solution had been added. Under these conditions, the present compounds now quickly assemble under potential (compare FIG. 3 with entries 1-3 in Table 2) and the thickness of the layer increases with time (Table 2 entries 1-3,14-16). Electron-donating groups, such as ethyl and methoxy groups, can aid in the formation of SAMs (entries 1, 17, 19). Electron-withdrawing groups, such as a nitro group (entries 8,12) and a quinone unit (entry 14) tend to retard the growth rate. After 2 min, at +400 mV, most of the layers from electron-donating group-containing molecules reached their full 5 length on the Au electrodes. (The molecular length of these compounds is 2.1 nm). Conversely, the compounds with strong electron-withdrawing groups were unable to assemble to their full length in 2 min. The right conditions for a complete monolayer coverage depend on the structure of the molecular device and have to be determined for each individual molecule. 2 min adsorption time on a Au surface at +400 mV positive potential are just right for the compounds 1(a) and 1(b), too short for 1(c) and 1(d), and too long for 1(e) and 1(f).

For mono-thioacetate molecular device components, the thickness of the assembled layers roughly correlates with the molecular length. One exception is compound (e), for which the layer is thicker than the length of the molecule (entries 17,18). It is speculated that the excess adsorption in the case of the unfunctionalized phenylene-ethynylene-oligomers (e) and (h) is caused by their lower solubility in ethanol. A similar phenomenon has been observed in the self-assembly of long chain alkanethiols on Au from ethanol which gave a layer 20 % thicker than the length of the molecule. Dithioacetates also formed multilayers upon extended assembly times, presumably due to disulfide formation as promoted by trace oxygen or the applied electric potential. To obtain a monolayer of dithioacetate molecular devices, a short assembly time in an atmosphere excluding oxygen should be employed.

We attempted to remove the layers assembled by the foregoing process, but once dried, the layer thicknesses remained virtually unchanged after sonication in THF, indicating that the excess molecules were either chemically bonded to the under layer or had been oxidized to the even less soluble disulfides.

TABLE 2
Thickness measurement for the potential-driven
assembled film on Au and Pt surface

| | Compound | | Potential | | |
|---|---|---|---|---|---|
| Entry | (FIG. 1) | Surface | (mV vs Ag/AgNO₃) | Time | Thickness |
| 1 | (a) | Au | +400 | 2 min | 2.9 nm |
| 2 | (a) | Au | +400 | 6 min | 3.2 nm |
| 3 | (a) | Au | +400 | 10 min | 4.3 nm |
| 4 | (a) | Au | −800 | 10 min | 1.0 nm |
| 5 | (a) | Au | −1000 | 10 min | 0.5 nm |
| 6 | (a) | Pt | +400 | 2 min | 2.0 nm |
| 7 | (a) | Pt | +400 | 10 min | 3.6 nm |
| 8 | (b) | Au | +400 | 2 min | 2.0 nm |
| 8b | (b) | Au | +0 | 15 min | 0.4 nm |
| 9 | (b) | Au | +400 | 10 min | 2.2 nm |
| 10 | (b) | Pt | +400 | 2 min | 0.7 nm |
| 11 | (b) | Pt | +400 | 10 min | 2.1 nm |
| 12* | (c) | Au | +400 | 2 min | 0.4 nm |
| 13* | (c) | Au | +400 | 20 min | 1.5 nm |
| 14 | (d) | Au | +400 | 2 min | 0.3 nm |
| 15 | (d) | Au | +400 | 10 min | 0.8 nm |
| 16 | (d) | Au | +400 | 20 min | 1.8 nm |
| 17 | (e) | Au | +400 | 2 min | 3.3 nm |
| 18 | (e) | Au | +400 | 10 min | 3.9 nm |
| 19 | (f) | Au | +400 | 2 min | 2.2 nm |
| 20 | (f) | Au | +400 | 10 min | 6.1 nm |

*The base used here was concentrated ammonium hydroxide (20 μL).

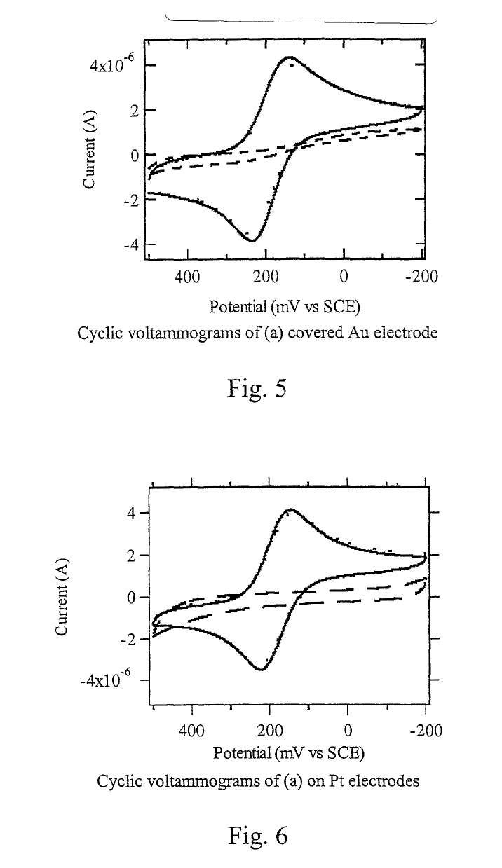

FIG. 5 shows the CV of an gold electrode covered with (a). It compares CV data from a bare gold electrode (solid line in FIG. 5), a covered gold electrode assembled without potential for 2 min (dotted line in FIG. 5), and a covered gold electrode assembled with potential for 2 min (dashed line in FIG. 5). In 2 min, nearly 100% of the gold surface was covered with a layer of (a). As shown in FIG. 5, assembly of the molecules with applied potential significantly faster than without applied potential.

All of the CVs in FIG. 5 were recorded in an aqueous solution of KCl/K₃[Fe(CN)₆] (0.1 M/1 mM). The dotted line represents an electrode prepared without potential by immersing a rode for 2 min in a 20 mL ethanolic solution containing (a) (1.0 mg, 2.1 μmol), Bu₄NBF₄(0.33 g, 1 mmol), and aqueous solution of NaOH (20 μL, 5.4×10⁻³ mmol). The dashed line represents an electrode obtained by applying +400 mV (vs Ag/AgNO₃ electrode) on a bare gold electrode for 2 min in a 20 mL ethanolic solution of (a) (0.1 mM), Bu₄NBF₄ (0.05 M), with aqueous solution of NaOH (20 μL, 5.4×10⁻³ mmol).

The present technique of assembly under electric potential works on platinum also. Table 2 above includes data for the potential-assisted assembly of compounds (a) and (b) on platinum (entries 6,7,10,11). Layers of molecular device components grow more slowly on platinum than on gold. FIG. 6 shows cyclic voltammograms of a platinum electrode covered with (a) made by the potential assembly technique. In 10 min, the surface coverage ratio was nearly 100%. In contrast, the conventional chemical self-assembly of 1 on platinum, under the same conditions of base concentration, was very slow. After immersion of a platinum electrode in a solution of 1 in ethanol for 10 min, the surface coverage ratio was only ˜5% (FIG. 4).

All of the three cyclic voltammograms in FIG. 6 were recorded in an aqueous solution of KCl/K3[Fe(CN)6] (0.1 M/1 mM). The solid line represents the bare platinum electrode; the dotted line represents the platinum electrode prepared without potential by immersing for 10 min in an ethanol solution (20 mL) of (a) (1.0 mg, 2.1 μmol), Bu₄NBF₄ (0.33 g, 1 mmol), NaOH (20 μL, 5.4×10⁻³ mmol); and the dashed line represents the platinum electrode prepared by applying +400 mV (vs Ag/AgNO₃ electrode) on a bare platinum electrode for 10 min in the same solution.

From this point of view, platinum electrodes are better than gold electrodes because thiols grow more slowly on platinum than on gold via conventional chemical self-assembly. Under electric potential, the growth rates are nearly the same, although slightly slower on platinum. This greater disparity results in a wider operation time window for the controlled deposition of molecular device components. Put another way, the unbiased platinum electrode will be even cleaner than the unbiased gold electrode under the same conditions.

The foregoing paragraphs discuss the formation of a SAM of molecular device components on the surface of a gold or platinum substrate under positive electric potential. Conversely, as discussed above, a negative potential can prevent the formation of this layer. Table 2 lists the results of the application of (a) to a gold electrode under negative potential (entries 4,5). When the applied potential is sufficiently negative, the growth of the molecular devices on the gold electrodes can be slowed significantly.

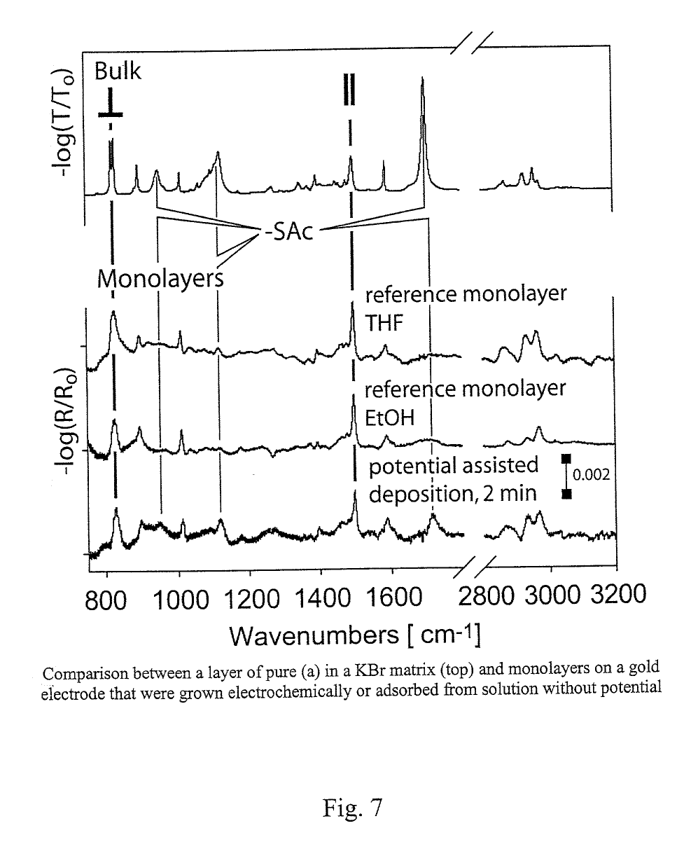

FIG. 7 shows the IR spectrum of polycrystalline (a) dithioacetate in a KBr matrix (top) and the spectra of three monolayers on gold. One of the monolayers was deposited under electric potential and the other two were deposited without applied potential. The monolayer from the adsorption with applied potential still has about half of its thioacetate groups uncleaved. We assume that the uncleaved ends are mostly at the film-air interface because no thioacetate bands were observed in the IR spectra of monolayers from partially cleaved monothioacetate solutions on gold.

The intrinsic band intensities can be determined from the transmission spectrum of a polycrystalline bulk sample, diluted with KBr and pressed into a transparent pellet. Differences between the intensities in the monolayer and bulk spectrum indicate an anisotropic film in which the molecules are aligned in a preferential direction. A semi-quantitative analysis is possible if the bulk and monolayer spectrum have at least two sufficiently intense bands with different orientations, i.e. parallel or perpendicular to the molecular main axis. Similar relative intensities for these two bands in the monolayer and bulk spectrum indicate that the molecules are either randomly oriented or that the molecules may be uniformly tilted by ˜54.7° (magic angle) from the surface normal.

Not all IR bands can be used for such a semi-quantitative analysis. Some of the bands are more sensitive to the changes in intermolecular distances and mobility. The best bands for a semi-quantitative analysis have the same position and width-at-half-height in the monolayer and polycrystalline bulk phase. The parallel mode at 1499 cm⁻¹ falls into this category. Among the perpendicular modes we can only take the doublet at 830/822 cm⁻¹ in the bulk spectrum that changes into a single band at 826 cm¹ in the monolayer spectrum. The ratio of the integrated areas of these two bands are 0.61:1 and 0.62:1 for the chemically and potential-driven deposited monolayers respectively. This ratio also agrees with the result from the reference spectrum of the polycrystalline sample (0.58:1). The fast potential-driven deposition and the standard 24 h adsorption give monolayers with identical orientation. The molecules do not lie flat on the surface as they do at submonolayer coverages, but the higher coverage is not enough to reach an upright orientation.

In FIG. 7, transmission (T) and reflection (R) spectra are reported in absorbance units, defined as −log (T/T₀) and −log(R/R₀). The deposition under potential was done in 2 min in a solution of 20 mL ethanol with 2 μmol of 1 and 5 μmol of NaOH with a positive potential of 400 mV. The other two monolayers were prepared over 17 hours from THF with ammonium hydroxide as the base and from ethanol with NaOH as the base, respectively.

Self-Assembly of Thiolates on Gold Using Acid Deprotection.

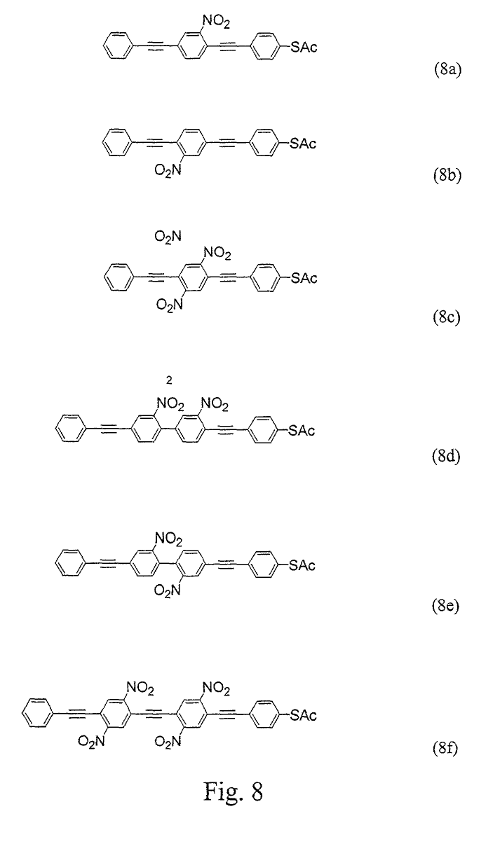

The concepts of the present invention have applicability to systems other than base-activated systems. Specifically, some molecular devices, including those shown in FIG. 8, can be selectively applied using acid deprotection, as described in detail below.

Gold Substrates

A single crystal silicon wafer was cut in 6×16 mm² sheets, then cleaned for 30 min in a hot (40° C.) fresh acidic peroxide (3:1 H₂SO₄/H₂O₂, v/v) solution, rinsed with a flowing distilled-water, ethanol and acetone, and the pieces of Si were dried in a flowing ultrahigh purity N₂ gas. The gold films were deposited by thermal evaporation of 200 mn thick Au onto the Si sheets with a 25 nm Cr adhesion layer at a rate of 1 Å/s under the vacuum of 2×10⁻⁶ Torr. The gold samples were finally stored in a N₂ atmosphere. Before use, the gold substrates were cleaned by a UV/O₃ cleaner (Boekel Industries, Inc., Model 135500) for 10 min in order to remove organic contamination, followed by ultrasonic cleaning in ethanol for 20 min to remove the resulting gold oxide layer, rinsing with ethanol and acetone, then dried in flowing N₂. This procedure was confirmed to provide a clean, reproducible gold surface.

Chemicals

Methylene chloride (CH₂Cl₂) and acetonitrile were distilled from calcium hydride. Tetrahydrofuran was distilled from sodium/benzophenone ketyl. All other chemicals were used as received without further purification. The syntheses of compounds such as those in FIG. 8 are well known. See, for example, Chem. Eur. J. 2001, 7, No. 23, 5118-5134, cited above.

Solution Preparation for Acid-Promoted Method

The compound (1 mg) was dissolved with a solvent mixture of CH₂Cl₂/MeOH (2:1, v/v) in a 4 mL vial. 50-70 μL of concentrated H₂SO₄ was then added and the solution was incubated for 1-4 h in order to give deprotection of thiol moiety.

Chemical Assembly

The cleaned gold substrates were immersed into the adsorbate solutions at room temperature for a period of 20-24 h. All the solutions were freshly prepared, previously purged with N₂ for an oxygen-free environment and kept in the dark during immersion to avoid photo-oxidation. After the assembly, the samples were removed from the solutions, rinsed thoroughly with acetone, MeOH and CH₂Cl₂, and finally blown dry with N₂.

Potential-Assisted Assembly

The same three-electrode cell described above was used with a gold substrate as the working electrode, a platinum wire as the counter electrode, and an Ag/AgNO₃ (10 mM AgNO₃ and 0.1 M Bu₄NBF₄ in acetonitrile) reference electrode. The monolayers were deposited by the constant potential of 400 mV for 5-60 min in the SAM solutions. After the modification, the samples were removed from the solutions, rinsed with acetone, MeOH and CH₂Cl₂, and blown dry with N₂.

Electrochemical Measurement

Cyclic voltammetry (CV) for SAM formation was performed in an aqueous solution with 1 mM K₃[Fe(CN)₆] and 0.1 M KCl between −0.2 and +0.6 V (vs. SCE) at the rate of 100 mV/s. An Au disk electrode (MF-2014, BAS) with diameter 1.6 mm was used as the working electrode, a saturated calomel electrode (SCE) as a reference electrode and a Pt wire as a counter electrode.

Ellipsometry

Monolayer thickness was determined using a Rudolph series 43 1A ellipsometry. The He—Ne laser (632.8 nm) light was incident at 70° on the sample. Measurements were carried out before and immediately after monolayer adsorption. All the thickness was calculated based on the refractive index of n_{f}=1.55. The length of the molecular wire was calculated from a sulfur atom to the furthest proton for the minimum energy extended forms by molecular mechanics. The theoretical thickness was then obtained with the assumed linear Au—S—C bond angles and 0.24 nm for the Au—S bond length.

UV-Vis Spectroscopy

The UV-Vis spectroscopes were recorded by UV-Vis-NIR scanning spectrophotometer (Shimadzu, UV-3101 PC).

Discussion

As described above, the thiolacetyl groups of molecular device compounds are easily deprotected to the free thiol or thiolate by deacylation with NH₄OH, and then the SAM are formed on a gold surface by Au—S bonding. Table 3 illustrates the chemical assembly of molecular wires in a single solvent. The measured thickness of mononitro compounds (1 and 2) are near to the theoretical values. It indicates a compact monolayer has been formed. On the other hand, the thickness of multi-nitro compounds exhibit a large difference compared to the calculated values. A slower rate of adsorption is detected. The strong electron-withdrawing nitro group reduces the interaction of Au and S, finally results in the slower assembly rate and the poor adsorption on Au surface. Moreover, the multi-nitro groups of conjugated molecules are possibly attacked by hydroxide during the long assembly time, which decomposes the compounds and induces a precipitation in the unstable solution accompanied by color changes from yellow-green to brown.

TABLE 3
Chemical assembly of thiolacetyl-terminated
molecular wires in a single solvent.

| | | | | Experimental | Calculated |
|---|---|---|---|---|---|
| | | | Time | Thickness | Thickness |
| Compound | Solvent | Base | (h) | (nm)^{a} | (nm)^{b} |
| (8a) | EtOH | NH₄OH | 24 | 2.4 | 2.14 |
| (8b) | EtOH | NH₄OH | 24 | 2.0 | 2.14 |
| (8c) | THF | NH₄OH | 24 | 1.0 | 2.14 |
| (8d) | THF | NH₄OH | 24 | 0.8 | 2.62 |
| (8e) | THF | NH₄OH | 24 | 0.7 | 2.62 |
| (8f) | THF | NH₄OH | 24 | 1.6 | 2.86 |

^{a}The value measured by ellipsometry.
^{b}The theoretical thickness calculated by molecular mechanics without the consideration of the tilt angle of molecular wire in SAM.

Thus, to get a well-ordered SAM of multi-nitro molecular wires, a mixed solvent is preferred and is selected based on the solubility and deprotection system. As shown in Table 4, the acetone/methanol solvent mixture performs best in the base-promoted method. All the SAM of dinitro compounds ((8c), (8d), (8e)) display thicknesses the same as the theoretical value after reaction of 24 h, thus complete assembly is achieved. Conversely, the tetra-nitro compound (8f) is not well assembled in the base-promoted system, as indicated by the relatively large difference between measured and theoretical thickness.

TABLE 4
Chemical assembly of thiolacetyl-terminated molecular wires in a mixed solvent.

| | | | | | Experimental | Calculated |
|---|---|---|---|---|---|---|
| | | | | Time | Thickness | Thickness |
| Compound | Solvent^{a} | Acid | Base | (h) | (nm) | (nm) |
| (8c) | Acetone/MeOH | — | NH₄OH | 24 | 2.0 | 2.14 |
| (8d) | Acetone/MeOH | — | NH₄OH | 24 | 2.5 | 2.62 |
| (8e) | Acetone/MeOH | — | NH₄OH | 24 | 2.4 | 2.62 |
| (8f) | Acetone/MeOH | — | NH₄OH | 24 | 2.0 | 2.86 |
| (8c) | Acetone/MeOH | — | Cs₂CO₃ | 24 | 2.4 | 2.14 |
| (8c) | CH₂Cl₂/MeOH | H₂SO₄ | — | 24 | 2.2 | 2.14 |
| (8d) | CH₂Cl₂/MeOH | H₂SO₄ | — | 24 | 2.4 | 2.62 |
| (8e) | CH₂Cl₂/MeOH | H₂SO₄ | — | 24 | 2.5 | 2.62 |
| (8f) | CH₂Cl₂/MeOH | H₂SO₄ | — | 24 | 2.9 | 2.86 |

^{a}The ratio of mixed solvent is 2:1.

An external electric field applied at the interface of liquid/gold can greatly change the assembly reaction rate and lead to a kinetically rather than thermodynamically controlled deposition process. UV-Vis spectra confirm that the acid-promoted method affords a more stable solution and it is reliable. Table 5 summarizes the results of potential-assisted assembly of various molecular wires on a gold electrode. The assembly rate is very fast and the SAM thickness increases with time. The rate of potential-assisted assembly is increased 10-100 times compared to the rate of the chemical assembly. In the base-promoted electrochemical assembly, the mononitro- and dinitro-compounds ((8a), (8c), (8e)) show a good assembly and near full-coverage on Au. The tetranitro compound (8f) slowly forms SAMs by base catalysis with either the potential-assisted procedure or the chemical method, as illustrated in Table 4. By using an acid-promoted electrochemical method, however, all the nitro-compounds ((8c), (8e), (8f)) can be completely assembled after a 60 min deposition time. The potential-assisted assembly is rapid and reproducible. UV-Vis spectra confirm that the acid-promoted method affords a more stable solution and it is reliable.

TABLE 5
Potential-assisted assembly of thiolacetyl-terminated molecular wires on gold electrode.

| | | | | Potential | Time | Reduced ratio of |
|---|---|---|---|---|---|---|
| Compound | Solvent^{a} | Acid | Base | (mV) | (min) | redox peak current^{b} |
| (8a) | EtOH | — | NH₄OH | 400 | 5 | 99% |
| (8c) | Acetone/MeOH | — | NH₄OH | 400 | 60 | 87% |
| (8e) | Acetone/MeOH | — | NH₄OH | 400 | 30 | 59% |
| (8e) | Acetone/MeOH | — | NH₄OH | 400 | 60 | 95% |
| (8f) | Acetone/MeOH | — | NH₄OH | 400 | 60 | 22% |
| Bare Au | | | | | | 0% |
| (8c) | CH₂Cl₂/MeOH | H₂SO₄ | — | 400 | 60 | 90% |
| (8e) | CH₂Cl₂/MeOH | H₂SO₄ | — | 400 | 60 | 97% |
| (8f) | CH₂Cl₂/MeOH | H₂SO₄ | — | 400 | 60 | 96% |

^{a}The ratio of mixed solvent is 2:1.
^{b}The reduced ratio of redox peak current is deduced by (1-I_{SAM}/I_{AU}) % from CVs in an aqueous solution of K₃[Fe(CN)₆]/KCl.

In the common chemical assembly, which is a passive incubation process, the open circuit potential (OCP) is about −200 to −300 mV. However, in an external positive electric field, the thiol and thiolate with negative charge can strongly adsorb on Au, therefore, a modest anodic potential (i.e., 400 mV) can greatly enhance the assembly rate. A lower negative potential will impede the assembly reaction and even peel away the existing SAM. Conversely, a higher positive potential will induce the MeOH and Au oxidation, which also deform the SAM. By the carefully selection of potential and solution, different molecular wires can be deposited on different parts of one electric device for the construction of a more complex logic circuit.

The present invention includes the voltage-assisted assembly of molecular devices on a substrate, with and without the rate differentiation that is results from the use of a chemical inhibitor, such as an acetate group. Thus, it is within the contemplated scope of the invention to accelerate the rate of assembly of a layer of molecular devices on a substrate using a voltage potential.

While preferred embodiments of the present invention have been discussed in detail herein, it will be understood that various modifications could be made thereto without departing from the scope of the invention. For example, the molecular devices, protective groups, solvents, electrolytes, electrodes, substrates, substrate surfaces, deprotection mechanisms, and activation mechanisms can all be varied. In addition, order in which the various steps of the present methods are performed can be varied. Unless order is explicitly recited in the claims, the mere recitation of claim steps in an order is not intended to require that the steps be performed in that order, or that one step must be completed before the next step can begin.

What is claimed is:

1. A method for selectively assembling a molecular device on a first substrate, comprising:
(a) contacting the first substrate with a solution containing molecular device molecules;
(b) impeding bonding of the molecular device molecules to the substrate sufficiently that application of a voltage potential to the substrate results in assembly of the molecular device on the substrate at a rate that is at least 1.5 times the rate of assembly of the molecular device on a voltage-neutral substrate; and
(c) applying a voltage potential to the first substrate so as to cause the molecular device molecules to assemble on the first substrate.

2. The method according to claim 1 wherein application of a voltage potential to the substrate results in assembly of the molecular device on the substrate at a rate that is at least 2 times the rate of assembly of the molecular device on a voltage-neutral substrate.

3. The method according to claim 1 wherein application of a voltage potential to the substrate results in assembly of the molecular device on the substrate at a rate that is at least 10 times the rate of assembly of the molecular device on a voltage-neutral substrate.

4. The method according to claim 1 wherein application of a voltage potential to the substrate results in assembly of the molecular device on the substrate at a rate that is at least 100 times the rate of assembly of the molecular device on a voltage-neutral substrate.

5. The method according to claim 1, further including:
(d) providing a second substrate adjacent to the first substrate; and
(e) contacting the first and second substrates with a solution containing second-type molecular device molecules that are different from the molecular device molecules of step (a) such that said second-type molecular device molecules assemble on said second substrate.

6. The method according to claim 5, further including electrically connecting the molecular device molecules assembled on the first substrate with the second-type molecular device molecules assembled on the second substrate with a conducting material.

7. The method according to claim 1 wherein the bonding of the molecular device to the substrate is impeded by providing a protective group on the molecular device molecule.

8. The method according to claim 1 wherein the molecular device comprises an oligo(phenylene ethynylene).

9. The method according to claim 1 wherein the molecular device comprises a thiol-terminated oligo(phenylene ethynylene) and the solution includes a base.

10. A method for assembling a molecular circuit on a first substrate, comprising:
(a) providing a mixture comprising molecular device molecules in solution, each molecular device having a metal-bonding terminus protected by a protective group;
(b) removing the protective group from a portion of the molecular device molecules;
(c) activating the metal-bonding 1 terminii of the de-protected molecular device molecules;
(d) contacting the first substrate with the solution; and
(e) allowing the activated metal-bonding terminii to bond to the substrate such that the molecular devices assemble on the first substrate.

11. The method according to claim 10 wherein step (c) comprises providing a base in the solution.

12. The method according to claim 10 wherein step (c) comprises providing a acid in the solution.

13. The method according to claim 10 wherein step (c) comprises applying a voltage to the substrate.

14. The method according to claim 10 wherein the molecular device is an oligo(phenylene ethynylene).

15. The method according to claim 10 wherein the protective group is selected from the group consisting of: thioethers, S-diphenylmethyl thioethers, substituted S-diphenylmethyl thioethers, and S-triphenylmethyl thio ethers, substituted S-methyl derivatives, substituted S-ethyl derivatives, silyl thioethers, thioesters, thiocarbonate derivatives, thiocarbamate derivatives, and thioacetates/thiolacetates/thioacetyls.

16. The method according to claim 10 wherein the protective group comprises acetate.

17. The method according to claim 10, further including (f) attracting the activated molecular devices to the first substrate by applying a voltage potential to the substrate.

18. The method according to claim 17, further including repeating steps (a)-(f) with a second substrate and with second-type molecular devices that are different from the molecular devices assembled on the first substrate.

19. A method for assembling a molecular circuit on a metal substrate, comprising:
(a) providing a mixture comprising molecular device molecules in solution, each molecular device molecule having a metal-bonding group;
(b) contacting the metal substrate with the solution; and
(c) applying a voltage potential to the substrate so as to attract the metal-bonding groups to bond to the substrate such that the molecular devices assemble on the substrate.

20. A molecular circuit prepared by:
(a) contacting a first substrate with a solution containing molecular device molecules;
(b) impeding bonding of the molecular device molecules to the substrate sufficiently that application of a voltage potential to the substrate results in assembly of the molecular device on the substrate at a rate that is at least 1.5 times the rate of assembly of the molecular device on a voltage-neutral substrate; and
(c) applying a voltage potential to the first substrate so as to cause the molecular device molecules to assemble on the first substrate.

21. A molecular circuit prepared by:
(a) contacting a first substrate with a solution containing molecular device molecules;
(b) impeding bonding of the molecular device molecules to the substrate sufficiently that application of a voltage potential to the substrate results in assembly of the molecular device on the substrate at a rate that is at least 1.5 times the rate of assembly of the molecular device on a voltage-neutral substrate;
(c) applying a voltage potential to the first substrate so as to cause the molecular device molecules to assemble on the first substrate;
(d) providing a second substrate adjacent to the first substrate;
(e) contacting the first and second substrates with a solution containing second-type molecular device molecules that are different from the molecular device molecules of step (a) such that said second-type molecular device molecules assemble on said second substrate; and
(f) electrically connecting the molecular device molecules assembled on the first substrate to the second-type molecular device molecules assembled on the second substrate with a conducting material.
